(19) United States
(12) Patent Application Publication
(10) Pub. No.: US 2025/0080102 A1
(43) Pub. Date: Mar. 6, 2025

(54) POWER TRANSISTOR CLAMP CIRCUIT

(71) Applicant: Texas Instruments Incorporated, Dallas, TX (US)

(72) Inventors: Taisuke Kazama, Plano, TX (US); Mustapha El-Markhi, Richardson, TX (US); Avadhut Junnarkar, McKinney, TX (US)

(21) Appl. No.: 18/506,273

(22) Filed: Nov. 10, 2023

Related U.S. Application Data
(60) Provisional application No. 63/536,592, filed on Sep. 5, 2023.

(51) Int. Cl. H03K 17/082; H02H 9/04; H02M 1/14; H02M 3/156; H03K 17/687

(52) U.S. Cl. CPC H03K 17/0822; H02H 9/04; H02M 1/143; H02M 3/156; H03K 17/687

(57) ABSTRACT

Described embodiments include a voltage clamping circuit having a threshold-setting circuit with a threshold input and a threshold output. A switch has a first terminal coupled to the threshold input, a second switch terminal, and a switch control terminal. A first transistor is coupled between the threshold output and the switch control terminal, and has a first control terminal. A second transistor is coupled between the first control terminal and ground, and has a second control terminal. A first driver circuit has a first driver input and a first driver output. A second driver circuit has a second driver input coupled to the first driver input, and a second driver output. A third transistor is coupled between the threshold input and ground, and has a third control terminal that is coupled to the second control terminal and the second switch terminal.

### CROSS-REFERENCE TO RELATED APPLICATION

This application claims priority to U.S. Provisional Patent Application No. 63/536,592 filed Sep. 5, 2023, which is incorporated herein by reference in its entirety.

### BACKGROUND

This description relates to voltage clamp circuits, such as voltage clamp circuits useful for protecting transistors in high current applications (e.g. voltage converters). A DC-DC voltage converter is an electronic circuit that converts an input direct current (DC) voltage into one or more DC output voltages that are higher or lower in magnitude than the input DC voltage. A DC-DC voltage converter that provides an output voltage lower than the input voltage is a buck voltage converter. A DC-DC converter that provides an output voltage higher than the input voltage is a boost voltage converter.

Some DC-DC voltage converters include power transistors coupled to an energy storage component. The energy storage component may be an inductor or a transformer. Electrical energy is transferred through the energy storage component to a load by alternately turning the transistors on and off using a switching control signal. The amount of electrical energy transferred to the load is a function of the duty cycle of the transistors and the frequency of the switching control signal. DC-DC voltage converters can be used in electronic devices, particularly battery powered devices, such as portable cellular phones, laptop computers, and other electronic systems.

Transistor switching transients and ringing due to parasitic inductances in the voltage converter circuit can lead to the transistors being overstressed by voltages across the transistor exceeding the transistor breakdown voltage. When the voltage across a transistor exceeds its maximum voltage, the transistor is operating outside of its safe operating area. A voltage clamping circuit can be implemented to help minimize overvoltage conditions due to ringing.

### SUMMARY

In a first example, a voltage clamping circuit includes a threshold-setting circuit having a threshold input and a threshold output. A switch has first and second switch terminals, and a switch control terminal. The first switch terminal is coupled to the threshold input. A first transistor is coupled between the threshold output and the switch control terminal, and has a first control terminal. A resistor is coupled between the threshold output and the first control terminal. A capacitor is coupled between the first control terminal and a ground terminal.

A second transistor is coupled between the first control terminal and the ground terminal, and has a second control terminal. A first driver circuit has a first driver input and a first driver output. A second driver circuit has a second driver input and a second driver output, wherein the second driver input is coupled to the first driver input. A third transistor is coupled between the threshold input and the ground terminal, and has a third control terminal. The third control terminal is coupled to the second control terminal and the second switch terminal.

In a second example, a method for clamping a voltage in a circuit includes operating a switching power supply circuit having a high-side transistor and a low-side transistor. An input voltage supplied by a switch terminal connecting the high-side transistor and the low-side transistor is received by a threshold circuit. It is then determined whether the input voltage exceeds a threshold voltage.

A switch is closed responsive to the input voltage exceeding the threshold voltage, causing the switch terminal to be coupled to a transistor through the switch. The transistor is turned on using current from the switch. Turning on the transistor shorts the switch terminal to a ground terminal, causing the input voltage to fall. The switch is opened in response to the input voltage no longer exceeding the threshold voltage.

### BRIEF DESCRIPTION OF THE DRAWINGS

FIG. 1 shows a schematic diagram for an example DC-DC converter with a voltage clamping circuit.

FIG. 2 shows an example graph of the voltage at the switch terminal during transistor switching.

FIG. 3 shows an example graph of drain-source voltage ringing that can occur in a typical DC-DC voltage converter.

FIG. 4 shows a schematic diagram for an example DC-DC converter with a voltage clamping circuit having improved robustness against CHC stress.

### DETAILED DESCRIPTION

In this description, the same reference numbers depict same or similar (by function and/or structure) features. The drawings are not necessarily drawn to scale.

Efficiency is an important specification for DC-DC voltage converters. To increase efficiency, gate drivers provide rapid turn-on and turn-off the power transistors in the DC-DC voltage converter, and power transistors with a low on-resistance are used. However, rapid turn-on and turn-off increases ringing, which increases the drain-source voltage (V_{DS}) across the power transistors. The power transistors can be damaged if the V_{DS} exceeds the transistor's safe operating voltage. Power transistor breakdown voltage may decrease in conjunction with specific on-resistance, which increases the likelihood of transistor damage due to ringing overvoltage.

Ringing and stress on the power transistors increase when powering greater loads. Clamp voltage may also increase with load, which may result in damage to the power transistors. Negative current flow through the low-side power transistor to ground increases the likelihood of damage to the low-side power transistor.

Under nominal load conditions, ringing and stress of the power transistors is lower, and the clamp circuit may not be needed in order to protect the power transistors. In this case, the clamp circuit can be left inactivated to help increase efficiency. However, under higher load conditions, ringing and stress may be higher compared to nominal load conditions, and the clamp circuit may decrease the clamp voltage to protect the power transistors. The clamp circuits may also include a resistor-capacitor (RC) filter to dampen ringing and further protect the power transistors.

A trend in modern process technologies is to optimize power transistors to improve the specific resistance (R_{SP}) from generation to generation. This improvement in R_{SP} reduces conduction losses within a particular die area. However, this comes at the expense of lower breakdown voltages in the power transistor. To improve power efficiency, drive stages for power transistors may be designed with fast turn-on times to minimize switching losses. This results in higher voltage ringing due to parasitic loop inductances, and translates into higher V_{DS} across the power transistor.

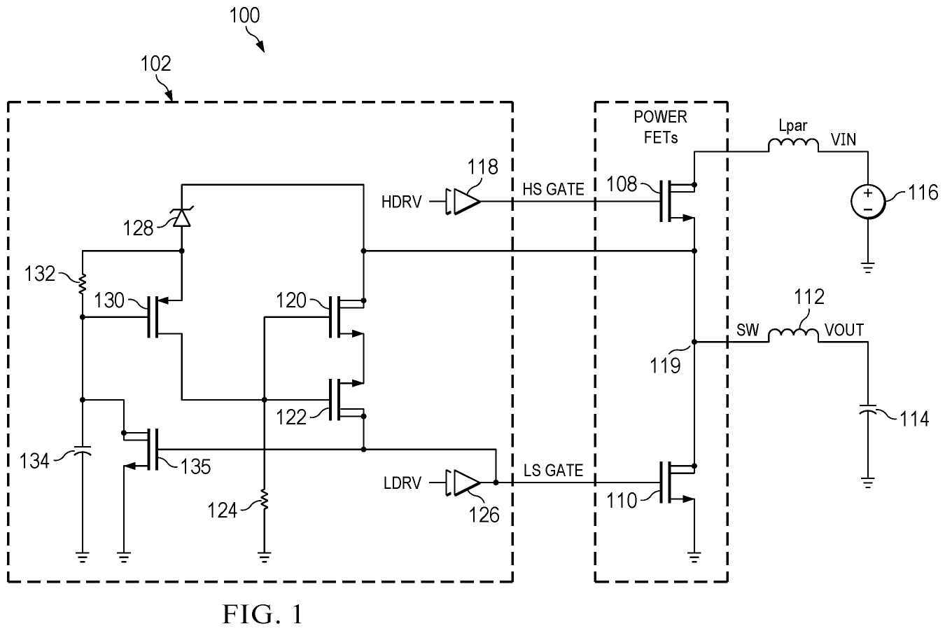

FIG. 1 shows a schematic diagram for an example clamp circuit 102 implemented in a DC-DC converter 100. The DC-DC converter 100 includes a high-side transistor 108, a low-side transistor 110, an inductor 112, and an output capacitor 114. In at least one case, high-side transistor 108 and low-side transistor 110 are n-channel field effect transistors (NFETs).

An input voltage source 116 (e.g., a battery or AC-DC power supply) provides an input DC voltage VIN. High-side transistor 108 is coupled between the input voltage source 116 and a switch terminal SW 119. The gate of high-side transistor 108 is coupled to the output of driver 118 and receives the signal HS GATE. A parasitic inductance Lₚₐᵣ may be coupled between input voltage source 116 and high-side transistor 108. The switch terminal SW 119 is coupled to a first terminal of inductor 112. Output capacitor 114 is coupled between a second terminal of inductor 112 and a ground terminal.

Low-side transistor 110 is coupled between the switch terminal SW 119 and a ground terminal. A drain of low-side transistor 110 is coupled to the source of high-side transistor 108. The gate of low-side transistor 110 is coupled to the output of driver 126 and receives the signal LS GATE. Driver 118 receives an input HDRV at its input and provides a first control signal HS GATE at its output. Driver 126 receives an input LDRV at its input and provides a second control signal LS GATE at its output.

Driver 118 and driver 126 charge and discharge the gate capacitances of high-side transistor 108 and low-side transistor 110, respectively. Parasitic inductance in DC-DC converter 100 (e.g. Lₚₐᵣ) can cause ringing at the drain and/or the source of high-side transistor 108 and low-side transistor 110 during switching. The voltage due to ringing can increase the V_{DS} across high-side transistor 108 and/or low-side transistor 110, potentially causing the transistors to become overstressed or damaged.

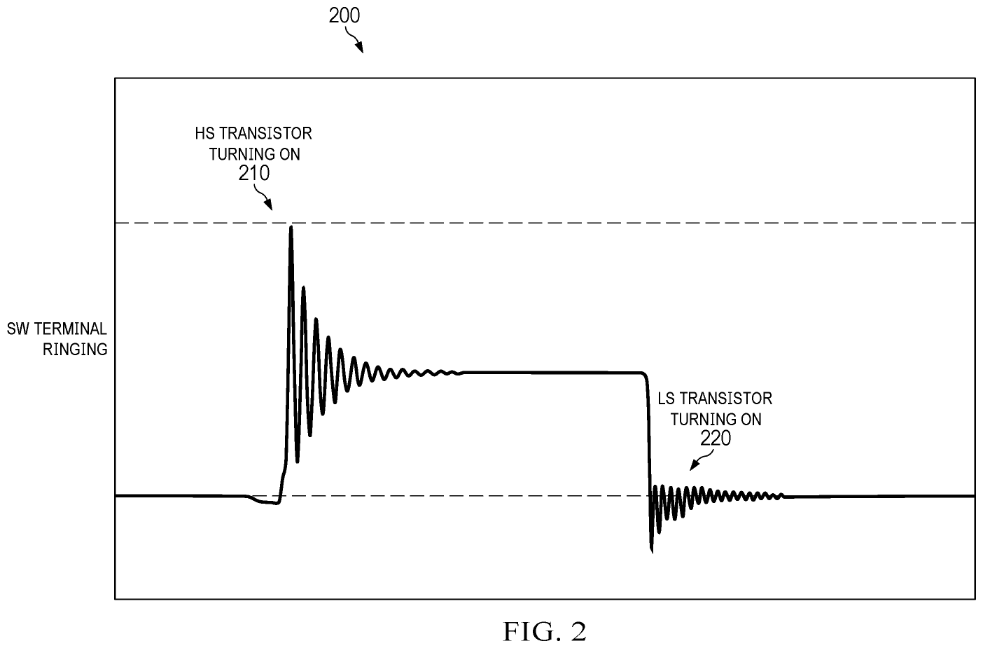

FIG. 2 shows an example graph 200 of the voltage at the switch terminal SW 119 during transistor switching. At time 210, the high-side transistor 108 turns on, causing the voltage at the switch terminal SW 119 to rise higher than the input voltage VIN due to a switching transient. Immediately following the initial peak at time 210, the voltage at the switch terminal SW 119 continues to ring due to parasitic inductances in the circuit. The ringing continues until the energy from the ringing dissipates. At time 220, the low-side transistor 110 turns on, causing the voltage at the switch terminal SW 119 to fall below the negative voltage rail or ground due to a switching transient. Immediately following the initial negative transient at time 220, the voltage at the switch terminal SW 119 continues to ring due to parasitic inductances in the circuit. The ringing continues until the energy from the ringing dissipates.

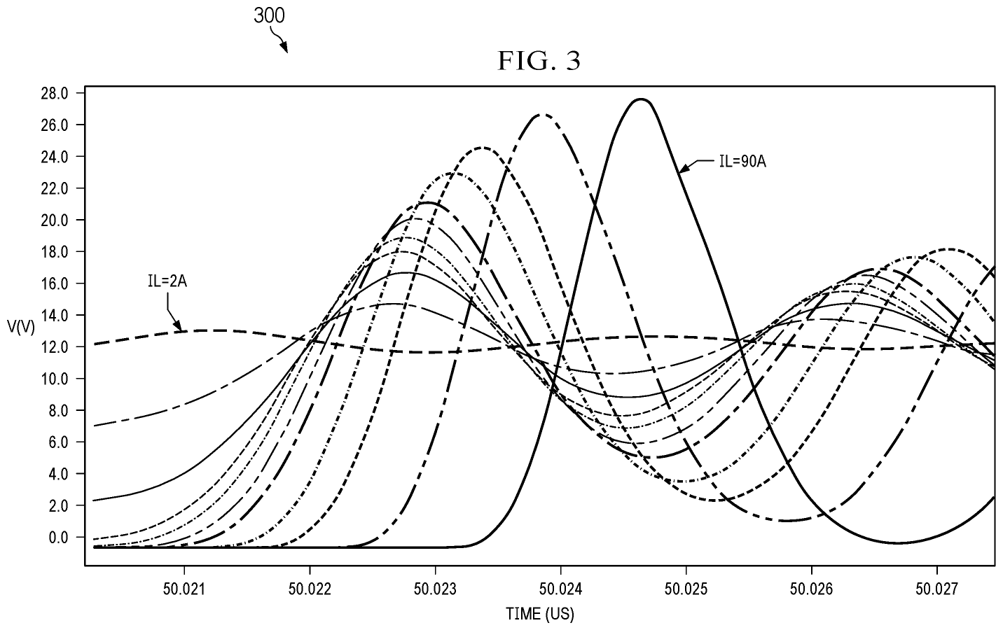

FIG. 3 shows an example graph 300 of drain-source voltage ringing that can occur in a typical DC-DC voltage converter. A family of curves representing the drain-source voltage ringing at the low-side power transistor with load currents ranging from 2 amperes to 90 amperes is shown in graph 300. In the example of graph 300, the voltage ringing as measured at the switch terminal SW can be in a range from 12V to 28V with load currents ranging from 2 amperes to 90 amperes.

When this type of voltage ringing occurs at the switch terminal SW 119, the V_{DS} of transistors 108 and 110 can exceed their breakdown voltages unless some measure is added to limit the excessive voltage. An example of such a measure is adding a clamp circuit to limit the V_{DS} of transistors 108 and 110, such as claim circuit 102 in DC-DC converter 100.

Clamp circuit 102 is coupled to high-side transistor 108 and low-side transistor 110 to suppress ringing and to clamp the voltage at the source of the high-side transistor 108 and the drain of the low-side transistor 110 below a threshold voltage. Clamp circuit 102 provides a switchable path for current flow to ground if the voltage at the source of high-side transistor 108 and the drain of low-side transistor 110 exceeds the threshold voltage. This threshold voltage is set by a zener diode 128. Zener diode 128 could be a zener diode or any other type of voltage clamping circuit capable of performing a similar function, or of setting a threshold voltage.

Clamp circuit 102 includes transistor 120, transistor 122, resistor 124, zener diode 128, transistor 130, resistor 132, capacitor 134, and transistor 135. In at least one case, transistors 120, 122, and 135 are NFETs, and transistor 130 is a p-channel field effect transistor (PFET). A first current terminal (e.g., drain) of transistor 120 is coupled to the drain of low-side transistor 110. A second current terminal (e.g., source) of transistor 120 is coupled to a first current terminal (e.g., source) of transistor 122. A second current terminal (e.g., drain) of transistor 122 is coupled to the control terminal of low-side transistor 110 and to a control terminal of transistor 135.

Transistors 120 and 122 allow current to flow from the switch terminal SW 119 to the gate of low-side transistor 110. In some implementations of clamp circuit 102, transistor 122 may be replaced by a diode having an anode coupled to the source of transistor 120, and a cathode coupled to the gate of low-side transistor 110. The control terminal of transistor 120 is coupled to the control terminal of transistor 122. Resistor 124 is coupled between the control terminal of transistor 122 and the ground terminal.

Transistor 130 is coupled between zener diode 128 and the control terminal of transistor 122. Resistor 132 is coupled between zener diode 128 and the control terminal of transistor 130, and is in parallel with the gate-to-source junction of transistor 130. Capacitor 134 is coupled between the control terminal of transistor 130 and the ground terminal.

Clamp circuit 102 is acting to control low-side transistor 110. When the high-side transistor 108 turns on, a relatively high ringing voltage may occur at the switch terminal SW 119 if the high-side transistor 108 is turned on fast. This ringing voltage will activate clamp circuit 102 if the ringing voltage is higher than the reverse breakdown voltage of zener diode 128. If this occurs, zener diode 128 will conduct current from the switch terminal SW through transistor 130. When transistor 130 turns on, the gates of transistor 120 and transistor 122 will be pulled up, turning both transistor 120 and transistor 122 on. When transistor 120 and transistor 122 turn on and conduct current, the voltage at the gate of the low-side transistor 110 will rise, turning on low-side transistor 110, which will bring the voltage at the switch terminal SW 119 down.

Clamp circuit 102 operates as a feedback loop. When the voltage at the switch terminal SW 119 goes above the reverse breakdown voltage of zener diode 128, transistor 130 is turned on, which turning on transistors 120 and 122. This causes low-side transistor 110 to turn on, which brings down the voltage at the switch terminal SW 119, creating a feedback loop that keeps the voltage at switch terminal SW 119 below a threshold voltage. The threshold voltage is equal to the reverse breakdown voltage of zener diode 128 plus a delta voltage. The delta voltage, which in some cases could be around 5V, is equal to V_{DS} of transistor 130 plus the voltage at the gate of transistor 122.

With clamp circuit 102 inactive, the voltage across capacitor 134 is zero volts. When clamp circuit 102 activates, the voltage at the source of transistor 130 increases, but the voltage at the gate of transistor 130 does not follow the voltage at its source. Transistor 130 will turn on because the dV/dt is high enough that it does not allow capacitor 134 to charge up. So, during that short time period, transistor 130 is turned on, which pulls up each of the gates of transistors 120 and 122, causing transistors 120 and 122 to turn on. When transistors 120 and 122 turn on, they pull up on the gate of the low-side transistor 110.

However, the gate of low-side transistor 110 will be pulled up only if the current sourced from transistors 120 and 122 overcomes the output of driver 126, which is pulling down and trying to keep low-side transistor 110 turned off because high-side transistor 108 is turned on, which is the cause of the ringing. When high-side transistor 108 is turned on, low-side transistor 110 is turned off, so the LDRV signal is trying to keep low-side transistor 110 turned off. So, the drive from the clamp circuit including transistor 122 must be stronger than the pull-down of the output of driver 126 in order to turn on low-side transistor 110.

When clamp circuit 102 activates and pulls up the gate of low-side transistor 110, the voltage at the gate of low-side transistor 110 goes high. When the gate of low-side transistor 110 goes high, the voltage on the gate of transistor 135 rises and turns on transistor 135, which prevents capacitor 134 from charging. This keeps clamp circuit 102 activated until the energy from the ringing at the switch terminal SW 119 dissipates. After the energy from the ringing at the switch terminal SW 119 dissipates, transistors 120 and 122 will no longer be turned on, so low-side transistor 110 will no longer be turned on.

While turning on low-side transistor 110 can be effective for dissipating a ringing voltage at the switch terminal SW 119, it can make low-side transistor 110 susceptible to channel hot carrier (CHC) degradation, which can affect its reliability. Channel hot carriers in semiconductors have very high kinetic energy, and can generate electron-hole pairs near the drain of the transistor due to impact ionization from atomic level collisions. The effects of CHC degradation can cause degradation of the threshold voltage (VT), the linear drain current (I_{DLT}), and the saturated drain current (I_{DSAT}) of the transistor.

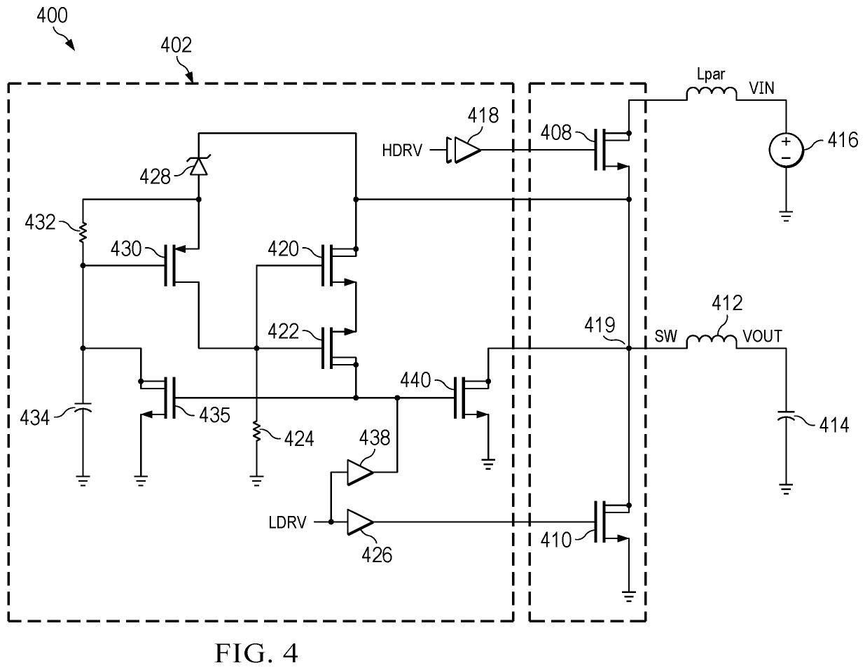

FIG. 4 shows a schematic diagram for an example DC-DC converter 400 with a voltage clamping circuit having improved robustness against CHC stress. In DC-DC converter 400, instead of using the low-side transistor for dissipating energy from ringing during operation of the clamp circuit, a separate smaller but higher voltage transistor is used for the same purpose for dissipating energy from ringing. This allows use of a lower voltage transistor for the low-side transistor. A higher voltage rated transistor is turned on during the voltage clamping, and will be stressed, but will be more resistant to damage from CHC because of its higher voltage rating. When the low side transistor is turned on, transistor 440 is also turned on, so transistor 440 is used in both modes of operation.

DC-DC converter 400 includes a high-side transistor 408, a low-side transistor 410, an inductor 412, and an output capacitor 414. In at least one case, high-side transistor 408 and low-side transistor 410 are n-channel field effect transistors (NFETs). However, in other examples, any of the field effect transistors in DC-DC converter 400 may be replaced by bipolar junction transistors (BJTs) with the gate, source and drain terminals replaced by base, emitter and collector terminals, respectively.

An input voltage source 416 (e.g., a battery or AC-DC power supply) provides an input DC voltage VIN. High-side transistor 408 is coupled between the input voltage source 416 and a switch terminal SW 419. The gate of high-side transistor 408 is coupled to the output of driver 418 and receives a gate drive signal. A parasitic inductance Lₚₐᵣ may be exist between input voltage source 416 and high-side transistor 408. The switch terminal SW 419 is coupled to a first terminal of inductor 412. Output capacitor 414 is coupled between a second terminal of inductor 412 and a ground terminal.

Low-side transistor 410 is coupled between the switch terminal SW 419 and a ground terminal. A drain of low-side transistor 410 is coupled to the source of high-side transistor 408. The gate of low-side transistor 410 is coupled to the output of driver 426 and receives a gate drive signal. Driver 418 receives a signal HDRV at its input and provides a first gate control signal at its output. Driver 426 receives a signal LDRV at its input and provides a second gate control signal at its output.

Driver 426 and driver 418 charge and discharge the gate capacitances of high-side transistor 408 and low-side transistor 410, respectively. Parasitic inductance in DC-DC converter 400 (e.g. Lₚₐᵣ) can cause ringing at the drain and/or the source of high-side transistor 408 and low-side transistor 410 during switching. The voltage due to ringing can increase the V_{DS} across high-side transistor 408 and/or low-side transistor 410, potentially causing the transistors to become overstressed or damaged.

Clamp circuit 402 is coupled to high-side transistor 408, switch terminal SW 419, and low-side transistor 410 to suppress ringing and to clamp the voltage at the source of the high-side transistor 408 and the drain of the low-side transistor 410 below a threshold voltage. Clamp circuit 402 provides a switchable path for current flow to ground through transistor 440 if the voltage at the source of high-side transistor 408 and the drain of low-side transistor 410 exceeds the threshold voltage. This threshold voltage is set by zener diode 428. Zener diode 428 could be a zener diode or any other type of voltage clamping circuit capable of performing a similar function.

Clamp circuit 402 includes transistor 420, transistor 422, transistor 440, resistor 424, zener diode 428, transistor 430, resistor 432, capacitor 434, and transistor 435. In at least one case, transistors 420, 422, 440 and 435 are NFETs, and transistor 430 is a p-channel field effect transistor (PFET). However, in other examples, these field effect transistors may be replaced by bipolar junction transistors (BJTs) with the gate, source and drain terminals replaced by base, emitter and collector terminals, respectively.

A first current terminal (e.g., drain) of transistor 420 is coupled to the drain of low-side transistor 410. A second current terminal (e.g., source) of transistor 420 is coupled to a first current terminal (e.g., source) of transistor 422. Transistor 440 is coupled between the switch terminal SW 419 and a ground terminal. A second current terminal (e.g., drain) of transistor 422 is coupled to the control terminal of transistor 440 and to a control terminal of transistor 435.

Transistors 420 and 422 allow current to flow from the switch terminal SW 419 to the gate of transistor 440 when the ringing voltage exceeds a threshold voltage. The threshold voltage is equal to the reverse breakdown voltage of zener diode 428 plus a delta voltage. The delta voltage, which in some cases could be around 5V, is equal to V_{DS} of transistor 430 plus the voltage at the gate of transistor 422. The control terminal of transistor 420 is coupled to the control terminal of transistor 422, and the same current flowing through transistor 420 flows through transistor 422. Resistor 424 is coupled between the control terminal of transistor 422 and the ground terminal.

Transistor 430 is coupled between zener diode 428 and the control terminal of transistor 422. Resistor 432 is coupled between zener diode 128 and the control terminal of transistor 430, and is in parallel with the gate-to-source junction of transistor 430. Capacitor 434 is coupled between the control terminal of transistor 430 and the ground terminal.

DC-DC converter 400 has a similar structure to DC-DC converter 100. However, in DC-DC converter 400, the functionality of low-side transistor 110 is instead performed by two transistors, low-side transistor 410 and transistor 430. Low-side transistor 410 is a lower voltage transistor, and transistor 430 is a higher voltage transistor.

In one case, low-side transistor 410 is rated at 18V, and transistor 430 is rated at 20V. In at least one example case, the area of low-side transistor 410 is nine times the area of transistor 430. This saves silicon die area because the larger transistor, low-side transistor 410, is in a lower voltage process, while providing additional protection against CHC degradation because transistor 430, which will be subjected to a higher V_{DS} during clamping while conducting current. During clamping action, low-side transistor 410 is off VGS=0V and see the same VDS as transistor 440. Low-side transistor 410 is not subjected to CHC overstress because does not conduct current during active operation of clamping circuit 402.

The LDRV signal is provided to the inputs of both driver 426 and driver 438. When the LDRV signal is asserted high, low-side transistor 410 and transistor 430 are each turned on by drivers 426 and 438, respectively. However, the turning off of low-side transistor 410 and transistor 430 occurs independently. The gate of low-side transistor 410 is connected only to the output of driver 426, and will be turned off if the LDRV signal goes low independent of clamp circuit 402, and it is not controlled by the clamp circuit 402. The gate of transistor 440 is connected to both the output of driver 438 and to the drain of transistor 422.

In at least one case, driver 438 has a weaker drive capability than transistors 420 and 422 or driver 426. Driver 438 has a weaker drive capability so that clamp circuit 402 can overcome driver 438 and pull up the gate of transistor 440 and turn on transistor 440 when the ringing voltage at the switch terminal SW 419 exceeds a threshold voltage. The threshold voltage is equal to the reverse breakdown voltage of zener diode 428 plus a delta voltage. The delta voltage, which in some cases could be around 5V, is equal to V_{DS} of transistor 430 plus the voltage at the gate of transistor 422. Furthermore, a weaker driver takes less silicon area than a stronger driver, so making driver 438 weaker provides a silicon area savings over the size of driver 426. When clamp circuit 402 is activated, low-side transistor 410 will be turned off because high-side transistor 408 is turned on.

Clamp circuit 402 controls transistor 440 to provide a path from the switch terminal SW 419 to ground. When the high-side transistor 408 turns on, a relatively high ringing voltage may occur at the switch terminal SW 419 if the high-side transistor 408 is turned on fast. This ringing voltage will activate clamp circuit 402 if the ringing voltage is higher than the threshold voltage.

If the ringing voltage is higher than the reverse breakdown voltage of zener diode 428, zener diode 428 will conduct current from the switch terminal SW through transistor 430. When transistor 430 turns on, the gates of transistor 420 and transistor 422 will be pulled up, turning on both transistor 420 and transistor 422. When transistor 420 and transistor 422 turn on and conduct current, the voltage at the gate of the transistor 440 will rise, turning on transistor 440, which will bring the voltage at the switch terminal SW 419 down.

Clamp circuit 402 operates as a feedback loop. When the voltage at the switch terminal SW 419 goes above the reverse breakdown voltage of zener diode 428, transistor 430 is turned on, which turning on transistors 420 and 422. This causes transistor 440 to turn on, which brings down the voltage at the switch terminal SW 419, creating a feedback loop that keeps the voltage at switch terminal SW 419 below the reverse breakdown voltage of zener diode 428.

When clamp circuit 402 inactive, the voltage across capacitor 434 is zero volts. When clamp circuit 402 activates, the voltage at the source of transistor 430 increases, but the voltage at the gate of transistor 430 does not follow the voltage at its source. Transistor 430 will turn on because the dV/dt is high enough that it does not allow capacitor 434 to charge up. So, during that short time period, transistor 430 is turned on, which pulls up each of the gates of transistors 420 and 422, causing transistors 420 and 422 to turn on. When transistors 420 and 422 turn on, they pull up on the gate of transistor 440.

However, the gate of transistor 440 will be pulled up only if the current sourced from transistors 420 and 422 overcomes the output of driver 438, which is pulling down and trying to keep transistor 440 turned off because high-side transistor 408 is turned on, so LDRV is being held low. The drive current from transistor 422 must be stronger than the pull-down current from the output of driver 438 in order to turn on transistor 440.

When clamp circuit 402 activates and pulls up the gate of transistor 440, the voltage at the gate of transistor 440 goes high. When the gate of transistor 440 goes high, the voltage on the gate of transistor 435 rises and turns on transistor 435, which prevents capacitor 434 from charging. This keeps clamp circuit 402 activated until the energy from the ringing at the switch terminal SW 419 dissipates. After the energy from the ringing at the switch terminal SW 419 dissipates, transistors 420 and 422 will no longer be turned on, so transistor 440 will no longer be turned on.

In this description, “terminal,” “node.” “interconnection.” “lead” and “pin” are used interchangeably. Unless specifically stated to the contrary, these terms generally mean an interconnection between or a terminus of a device element, a circuit element, an integrated circuit, a device, or other electronics or semiconductor component.

In this description, “ground” includes a chassis ground, an Earth ground, a floating ground, a virtual ground, a digital ground, a common ground and/or any other form of ground connection applicable to, or suitable for, the teachings of this description.

In this description, the term “couple” may cover connections, communications or signal paths that enable a functional relationship consistent with this description. For example, if device A generates a signal to control device B to perform an action, then: (a) in a first example, device A is coupled to device B by direct connection; or (b) in a second example, device A is coupled to device B through intervening component C if intervening component C does not alter the functional relationship between device A and device B, so device B is controlled by device A via the control signal generated by device A.

In this description, even if operations are described in a particular order, some operations may be optional, and the operations are not necessarily required to be performed in that particular order to achieve specified results. In some examples, multitasking and parallel processing may be advantageous. Moreover, a separation of various system components in the embodiments described above does not necessarily require such separation in all embodiments.

Modifications are possible in the described embodiments, and other embodiments are possible, within the scope of the claims.

What is claimed is:

1. A voltage clamping circuit comprising:
a threshold-setting circuit having a threshold input and a threshold output;
a switch having first and second switch terminals and a switch control terminal, wherein the first switch terminal is coupled to the threshold input;
a first transistor coupled between the threshold output and the switch control terminal, and having a first control terminal;
a resistor coupled between the threshold output and the first control terminal;
a capacitor coupled between the first control terminal and a ground terminal;
a second transistor coupled between the first control terminal and the ground terminal, and having a second control terminal;
a first driver circuit having a first driver input and a first driver output;
a second driver circuit having a second driver input and a second driver output, wherein the second driver input is coupled to the first driver input; and
a third transistor coupled between the threshold input and the ground terminal and having a third control terminal, wherein the third control terminal is coupled to the second control terminal and the second switch terminal.

2. The voltage clamping circuit of claim 1, further comprising a third driver circuit having a third driver input and a third driver output.

3. The voltage clamping circuit of claim 1, wherein the switch includes:
a fourth transistor having first and second current terminals and a fourth control terminal, wherein the first current terminal is coupled to the threshold input, and the fourth control terminal is coupled to the first transistor; and
a fifth transistor having third and fourth current terminals and a fifth control terminal, wherein the third current terminal is coupled to the second current terminal, the fourth current terminal is coupled to the third control terminal, and the fifth control terminal is coupled to the fourth control terminal.

4. The voltage clamping circuit of claim 3, wherein the resistor is a first resistor, and the voltage clamping circuit is further comprising a second resistor coupled between the fourth control terminal and the ground terminal.

5. The voltage clamping circuit of claim 1, wherein the threshold-setting circuit includes a zener diode.

6. The voltage clamping circuit of claim 1, wherein the first driver circuit has a lower output current driving capability than the second driver circuit.

7. The voltage clamping circuit of claim 2, wherein the first driver circuit has a lower output current driving capability than the second driver circuit and the third driver circuit.

8. The voltage clamping circuit of claim 1, wherein the first transistor is a p-channel field effect transistor (PFET), and the second and third transistors are each n-channel field effect transistors (NFETs).

9. The voltage clamping circuit of claim 1, wherein a signal at the threshold input includes a ringing voltage.

10. A method for clamping a voltage in a circuit, comprising:
operating a switching power supply circuit having a high-side transistor and a low-side transistor;
receiving, by a threshold circuit, an input voltage supplied by a switch terminal connecting the high-side transistor and the low-side transistor;
determining whether the input voltage exceeds a threshold voltage;
closing a switch responsive to the input voltage exceeding the threshold voltage, causing the switch terminal to be coupled to a transistor through the switch;
turning on the transistor using current from the switch, shorting the switch terminal to a ground terminal, causing the input voltage to fall; and
opening the switch responsive to the input voltage no longer exceeding the threshold voltage.

11. The method of claim 10, wherein the input voltage includes a ringing voltage.

12. The method of claim 11, wherein the switch terminal is coupled to a first terminal of an inductor.

13. The method of claim 12, wherein a second terminal of the inductor is coupled to an output terminal of the switching power supply circuit.

14. The method of claim 10, wherein the transistor has a higher voltage rating than the low-side transistor.

15. A drive circuit comprising:
a high-side transistor coupled between a power supply input and a switching terminal, and having a high-side control terminal;
a low-side transistor coupled between the switching terminal and a ground terminal, and having a low-side control terminal; and
a voltage clamping circuit that includes:
a threshold-setting circuit having a threshold input and a threshold output, wherein the threshold input is coupled to the switch terminal;
a switch having first and second switch terminals and a switch control terminal, wherein the first switch terminal is coupled to the switching terminal;
a first driver circuit having a first driver input and a first driver output;
a second driver circuit having a second driver input and a second driver output, wherein the second driver input is coupled to the first driver input, and the second driver output is coupled to the low-side control terminal; and
a transistor coupled between the threshold input and the ground terminal and having a first control terminal, wherein the first control terminal is coupled to the first driver output.

16. The drive circuit of claim 15, wherein the transistor is a first transistor, and the voltage clamping circuit is further comprising:
a second transistor coupled between the threshold output and the switch control terminal, and having a second control terminal;
a resistor coupled between the threshold output and the second control terminal;
a capacitor coupled between the second control terminal and the ground terminal; and
a third transistor coupled between the second control terminal and the ground terminal, and having a third control terminal.

17. The drive circuit of claim 15, further comprising a third driver circuit having a third driver input and a third driver output, wherein the third driver output is coupled to the high-side control terminal.

18. The drive circuit of claim 16, wherein the switch includes:
a fourth transistor having first and second current terminals and a fourth control terminal, wherein the first current terminal is coupled to the threshold input, and the fourth control terminal is coupled to the second transistor; and
a fifth transistor having third and fourth current terminals and a fifth control terminal, wherein the third current terminal is coupled to the second current terminal, the fourth current terminal is coupled to the first control terminal, and the fifth control terminal is coupled to the fourth control terminal.

19. The drive circuit of claim 18, wherein the resistor is a first resistor, and the voltage clamping circuit is further comprising a second resistor coupled between the fourth control terminal and the ground terminal.

20. The drive circuit of claim 15, wherein the threshold-setting circuit includes a zener diode.

21. The drive circuit of claim 17, wherein the first driver circuit has a lower output current driving capability than the second driver circuit.
